(19) United States
(12) Patent Application Publication
(10) Pub. No.: US 2008/0013277 A1
(43) Pub. Date: Jan. 17, 2008

(54) Method Of Manufacturing A Hollow Circuit Substrate

(75) Inventors: Masafumi Ueda, Oyama-shi (JP); Mikio Kondou, Ashikaga-shi (JP); Yohei Ikawa, Oyama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Showa Denko K.K., Minato-ku (JP)

(21) Appl. No.: 11/576,979

(22) PCT Filed: Oct. 13, 2005
(86) PCT No.: PCT/JP05/19261

§ 371 Date: Sep. 17, 2007

Related U.S. Application Data
(60) Provisional application No. 60/619,034, filed on Oct. 18, 2004.

(30) Foreign Application Priority Data
Oct. 13, 2004 (JP) 2004-298286

(51) Int. Cl. H05K 7/20

(52) U.S. Cl. 361/696; 29/890.03

(57) ABSTRACT

A method of manufacturing a hollow circuit substrate, of two metal sheets brazed to each other in a laminated state with a bulging hollow circuit for ed between the two metal sheets. Of the upper and lower metal sheets for forming the hollow circuit, a circuit-forming bulging portion is formed in the upper metal sheet. A flux suspension is applied by screen printing to the upper surface of the lower metal sheet so as not to overlap the circuit-forming bulging portion to form flux films. The two metal sheets are stacked on each other so as to close off the opening of the circuit-forming bulging portion and are brazed to each other. This method prevents flux from remaining in a hollow circuit of a manufactured hollow circuit substrate.

### CROSS REFERENCE TO RELATED APPLICATIONS

This application is an application filed under 35 U.S.C. §111(a) claiming the benefit pursuant to 35 U.S.C. §119(e)(1) of the filing date of Provisional Application No. 60/619,034 filed Oct. 18, 2004 pursuant to 35 U.S.C. §111(b).

### TECHNICAL FIELD

This invention relates to a method of manufacturing a hollow circuit substrate. More particularly, it relates to a method of manufacturing a hollow circuit substrate which is used in a liquid-cooled heat dissipating apparatus for dissipating heat which is generated by heat generating bodies such as heat generating electronic components of electronic equipment such as notebook personal computers, two-dimensional display apparatuses, and projectors, or which is used in planar heat pipes used for cooling heat generating electronic parts such as IPM (intelligent power modules), IGBT (insulated gate bipolar transistors), and thyristors.

In this specification and in the claims, the term “aluminum” includes pure aluminum as well as aluminum alloys.

### BACKGROUND ART

Conventionally, as a method of dissipating heat generated by a heat generating electronic part of electronic equipment, there has been widely employed a method which uses an aluminum heat dissipating substrate whose one surface serves as a heat receiving surface to be brought into thermal contact with a heat generating electronic part, and a heat dissipating fin integrally provided on the other surface of the heat dissipating substrate. A heat generating electronic part is mounted to the heat receiving surface of the heat dissipating substrate, and air is supplied to the heat dissipating fin by use of a cooling fan, whereby heat generated by the heat generating electronic parts is released to the air through the heat dissipating substrate and the heat dissipating fin.

However, in recent electronic equipment, due to miniaturization and increases in performance, there is a tendency for the amount of heat which is generated by heat dissipating electronic parts to increase, and a sufficient heat generating performance can no longer be obtained by conventional methods. In addition, in notebook personal computers, two-dimensional display apparatuses, projectors, and the like, the noise generated by cooling fans is increasing, and it is not possible to provide the quietness which has come to be demanded of this equipment.

In order to solve these problems, in notebook personal computers, for example, a liquid cooling system is being adopted. This liquid cooling system is one which is equipped with a heat receiver which comprises a water jacket which is filled with a cooling liquid and which is secured to a CPU (a heat generating electronic part), and a cooling liquid circulating tube which has both ends connected to the heat receiver and circulates cooling liquid, with the heat receiver being disposed on the body of a personal computer having a keyboard and with the cooling liquid circulating tube extending to a display apparatus which is mounted on the body of the personal computer so as to be freely opened and closed (see Japanese Patent Application Laid-Open (kokal) No. 2002-182797).

However, in the liquid cooling system described in the publication, heat is dissipated only from the cooling liquid circulating tube, so the heat dissipating surface area is insufficient, and it has the problem that its heat dissipating efficiency is poor.

In view of the above, there has been conceived a liquid-cooled heat dissipating apparatus including a hollow circuit substrate, the entire of which is composed of two aluminum sheets brazed to each other in the form of a laminate and in which a bulging hollow circuit is formed between both aluminum sheets, wherein the bulging hollow circuit of the hollow circuit substrate forms a cooling fluid circulating passage, and a heat receiving portion is provided on one surface of the hollow circuit substrate and is brought into thermal contact with a heat generating body which is to be cooled by the cooling fluid flowing within the cooling fluid circulating passage.

In a notebook personal computer with a body having a keyboard and a display apparatus which is provided on the body so as to be freely opened and closed, such a liquid-cooled heat dissipating apparatus is provided within the housing of the body, and a CPU provided within the housing of the body thermally contacts the heat receiving portion.

The hollow circuit substrate of the liquid-cooled heat dissipating apparatus described above is manufactured by forming at least one of the two aluminum sheets to be formed into the hollow circuit from an aluminum brazing sheet, by forming a circuit-forming bulging portion in at least one of the aluminum sheets, and stacking up both aluminum sheets and brazing them.

As is well known, normally, when brazing an aluminum material, it is necessary to apply a flux. Conventionally, application of the flux was carried out by dipping the aluminum material in a flux suspension of flux suspended in water or by applying the flux suspension to the aluminum material by spray coating or roll coating.

However, with these coating methods, it is difficult to apply a flux suspension only to necessary portions, and excessive amounts of flux suspension end up being applied, and when these methods are employed for the manufacture of the above-described hollow circuit substrate, problems like the following occur. Namely, flux adheres to portions to which it is not necessary to apply flux, and the external appearance after brazing becomes ugly. In addition, flux remains in the hollow circuit after brazing, and the hollow circuit becomes plugged up and the flow resistance of the cooling fluid increases or the necessary amount of cooling fluid cannot be introduced into the hollow circuit. In any of these cases, there is the problem that the desired cooling performance cannot be obtained.

As a method of applying flux which can solve such problems, a method using electrostatic coating of flux powder is known, but in this case, equipment costs become high, a large amount of flux becomes necessary, and the cost of manufacturing a hollow circuit substrate becomes high.

The object of this invention is to solve the problems described above and to provide a method of manufacturing a hollow circuit substrate which can prevent flux from remaining inside a hollow circuit of the manufactured hollow circuit substrate.

### DISCLOSURE OF THE INVENTION

In order to achieve the objects described above, the present invention has the following modes.

(1) A method of manufacturing a hollow circuit substrate, the entire of which is composed of at least two metal sheets which are brazed to each other in a laminated state and in which a bulging hollow circuit is formed between the metal sheets,

characterized by forming a circuit-forming bulging portion in at least one of the two metal sheets for forming a hollow circuit; printing a flux suspension on a surface of one of the two metal sheets serving as a coating-side metal sheet, the surface facing the other metal sheet serving as an uncoating-side metal sheet, such that the flux suspension does not overlap the circuit-forming bulging portion, whereby a flux film is formed on the surface of the coating-side metal sheet; and stacking the metal sheets so as to close off the opening of the circuit-forming bulging portion and brazing the metal sheets.

(2) A method of manufacturing a hollow circuit substrate as set forth above in (1) wherein the printing of the flux suspension is carried out by screen printing.

(3) A method of manufacturing a hollow circuit substrate as set forth above in (1) wherein the concentration of flux in the flux suspension is 50-70% by mass.

(4) A method of manufacturing a hollow circuit substrate as set forth above in (1) wherein the average particle diameter of the flux in the flux suspension is at most 30 μm.

(5) A method of manufacturing a hollow circuit substrate as set forth above in (1) wherein the two metal sheets for forming a hollow circuit are made of aluminum, and of the two metal sheets, at least one of the metal sheets is formed from a aluminum brazing sheet having a brazing material layer on at least one of its surfaces, and the two metal sheets are brazed to each other using the brazing material layer of the aluminum brazing sheet.

(6) A method of manufacturing a hollow circuit substrate as set forth above in (1) wherein the coating-side metal sheet is coated with the flux suspension except for on its peripheral portion.

(7) A method of manufacturing a hollow circuit substrate as set forth above in (1) wherein a through hole is formed in at least one of the two metal sheets for forming a hollow circuit, and the flux suspension is applied to the coating-side metal sheet so as not to overlap the through hole.

(8) A hollow circuit substrate manufactured by the method set forth above in any of (1)-(7), wherein a bulging hollow circuit is formed between at least one set of two adjoining metal sheets.

(9) A liquid-cooled heat dissipating apparatus in which the bulging hollow circuit of the hollow circuit substrate set forth above in (8) forms a cooling fluid circulating passage, and a heat receiving portion which thermally contacts a heat generating body which is cooled by a cooling fluid flowing within the cooling fluid circulating passage is provided on one surface of the hollow circuit substrate.

(10) An electronic apparatus having a housing and a heat generating electronic part disposed within the housing, wherein a liquid-cooled heat dissipating apparatus as set forth above in (9) is disposed in the housing, and the heat generating electronic part is thermally contacted by the heat receiving portion of the hollow circuit substrate.

(11) A notebook personal computer having a body with a keyboard and a display apparatus which can be freely opened and closed provided on the body, wherein a liquid-cooled heat dissipating apparatus as set forth above in (9) is provided in the housing of the body, and a CPU disposed within the housing of the body thermally contacts the heat receiving portion.

(12) A planar heat pipe in which the bulging hollow circuit of the hollow circuit substrate as set forth above in (8) is endless, in which a working fluid is sealed within the bulging hollow circuit, whereby a heat pipe portion having a condenser portion and an evaporator portion is formed.

(13) A heat dissipating apparatus in which a heat dissipating fin is attached to at least one surface of the planar heat pipe as set forth above in (12) at a portion corresponding to the condenser portion of the heat pipe portion.

(14) A CNC machine tool having a heat dissipating apparatus as set forth above in (13), wherein a heat generating electronic part thermally contacts the evaporator portion of the heat pipe portion on at least one surface of the planar heat pipe of the heat dissipating apparatus.

According to a method of manufacturing a hollow circuit substrate as described above in (1), a circuit-forming bulging portion is formed on at least one of two metal sheets for forming a hollow circuit, a flux suspension is printed on a surface of one metal sheet, which serves as a coating-side metal sheet, the surface facing the other metal sheet, which serves as an uncoating-side metal sheet, so as not to overlap the circuit-forming bulging portion, and then the metal sheets are stacked up so as to close off the opening in the circuit-forming bulging portion and brazed, so a suitable amount of a flux suspension can be applied just to necessary portions, the formation of a flux film having a required pattern becomes possible, and the external appearance after brazing can be prevented from becoming ugly. In addition, a suitable amount of flux suspension can be applied just to necessary portions and the formation of a flux film having a required pattern becomes possible, so flux can be prevented from remaining in a hollow circuit after brazing. Accordingly, plugging up of the hollow circuit can be prevented, an increase in the flow resistance of the cooling fluid can be prevented, introduction of the necessary amount of cooling fluid into the hollow circuit becomes possible, and a desired cooling performance can be obtained.

According to the method of manufacturing a hollow circuit substrate as described above in (2), printing of a suitable amount of a flux suspension only on necessary portions can be carried out relatively easily and with certainty.

According to the method of manufacturing a hollow circuit substrate as described above in (3), a flux suspension can be uniformly applied without the occurrence of repelling or dripping of liquid after coating.

According to the method of manufacturing a hollow circuit substrate as described above in (4), a flux film which is formed by application of a flux suspension can be uniformly formed with a thin film thickness. Accordingly, falling off of flux after coating can be prevented. If the film thickness of a flux film is thick, there is the possibility of its falling off due to even a slight impact or under handling, and there is the possibility of problems developing with respect to the ease of brazing or the external appearance after brazing. In addition, the adhered amount of flux can be made small, so it has the effect of preventing plugging up of a circuit and of improving the external appearance after brazing.

According to the method of manufacturing a hollow circuit substrate as described above in (5), two metal sheets for forming a hollow circuit can be brazed relatively easily.

According to the method of manufacturing a hollow circuit substrate as described above in (6), flux is prevented from leaking from the peripheral portion of metal sheets to the outside during brazing, and the external appearance after brazing is improved.

According to the method of manufacturing a hollow circuit substrate as described above in (7), flux is prevented from leaking from through holes in a metal sheet to the outside during brazing, so the external appearance after brazing is improved.

### BRIEF DESCRIPTION OF THE DRAWINGS

FIG. 1 is an exploded perspective view of a liquid-cooled heat dissipating apparatus using a hollow circuit substrate manufactured by the method according to this invention.

FIG. 2 is a plan view of an upper metal sheet in which a circuit-forming bulging portion, projections, and through holes are formed by press working in a manufacturing method according to this invention.

FIG. 3 is a plan view showing a lower metal sheet to which a flux suspension is applied by screen printing to form a flux film in the manufacturing method according to this invention.

FIG. 4 is a partially omitted, enlarged cross-sectional view taken along line A-A of FIG. 2 showing the state in which both metal sheets are stacked on each other in the manufacturing method according to this invention.

### BEST MODE FOR CARRYING OUT THE INVENTION

Below, embodiments of this invention will be explained while referring to the drawings.

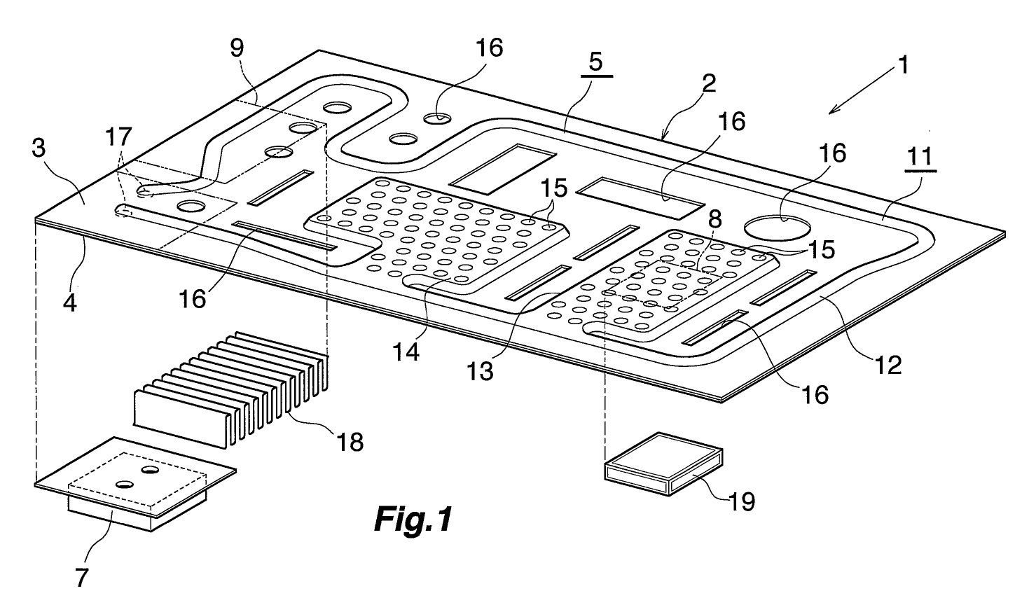

FIG. 1 shows the overall structure of a liquid-cooled heat dissipating apparatus using a hollow circuit substrate manufactured by a method according to this invention, and FIG. 2 to FIG. 4 show a method of manufacturing a hollow circuit substrate.

In FIG. 1, a liquid-cooled heat dissipating apparatus 1 has a planar hollow circuit substrate 2 made from an upper and lower sheet with a high thermal conductivity which are joined to each other in a laminated state and which in this case are aluminum metal sheets 3 and 4. A cooling fluid circulating passage 5 is formed between the metal sheets 3 and 4 of the hollow circuit substrate 2 as a hollow circuit.

A cooling fluid, such as antifreeze, which is not corrosive with respect to aluminum is sealed inside the cooling fluid circulating passage 5 in the hollow circuit substrate 2. The cooling fluid is circulated inside the fluid circulating passage 5 by a circulating pump 7 which is installed on the lower surface of the hollow circuit substrate 2. A heat receiving portion 8 and a heat dissipating portion 9 are provided on the lower surface of the hollow circuit substrate 2 so as to include a portion of the cooling fluid circulating passage 5. An unillustrated expansion tank is provided along the cooling fluid circulating passage 5 of the hollow circuit substrate 2.

Each of the two metal sheets 3 and 4 which make up the hollow circuit substrate 2 is made from an aluminum brazing sheet having a brazing material layer on one surface thereof. The two metal sheets 3 and 4 are brazed using the brazing material layer of the aluminum brazing sheet. Only one of the metal sheets may be an aluminum brazing sheet. In this case, the other metal sheet is a bare aluminum material.

A circuit-forming bulging portion 11 which bulges upwards and which has an opening closed off by the lower metal sheet 4 is formed in the upper metal sheet 3. The cooling fluid circulating passage 5 is formed by closing off the downwards-facing opening of the circuit-forming bulging portion 11 by the lower metal sheet 4. The circuit-forming bulging portion 11 comprises a first portion 12 which is formed around nearly the entire circumference of the peripheral portion of the upper metal sheet 3 and which has its two ends near to each other, and second and third portions 13 and 14 which connect to the first portion 12 and spread inwards by a prescribed amount. A large number of projections 15 which project inwards and which have their tip portions brazed to the lower metal sheet 4 are formed in the upper wall of the second and third portions 13 and 14. A plurality of through holes 16 are formed in the upper metal sheet 3 so as to avoid the circuit-forming bulging portion 11.

Through holes 17 by means of which both ends of the first portion 12 of the circuit-forming bulging portion 11 of the upper metal sheet 3 open onto the bottom surface of the hollow circuit substrate 2 are formed in the lower metal sheet 4. One of the through holes 17 is connected to the discharge port of the circulating pump 7, and the other through hole 17 is connected to the intake port of the circulating pump 7. The heat receiving portion 8 is provided in a location on the lower surface of the lower metal sheet 4 corresponding to the center of the second portion 13 of the circuit-forming bulging portion 11 of the upper metal sheet 3. A corrugated aluminum heat dissipating fin 18 is brazed to the bottom surface of the lower metal sheet 4 so as to include a portion of the first portion 12 of the circuit-forming bulging portion 11 of the upper metal sheet 3. As a result, a heat dissipating portion 9 including a portion of the cooling fluid circulating passage 5 is provided on the lower surface of the hollow circuit substrate 2.

The unillustrated expansion tank portion has a structure such that it takes in and holds air contained in the cooling fluid in the form of bubbles, and such that it also takes in cooling fluid when the cooling fluid is heated and expands and prevents damage to the cooling fluid circulating passage 5 due to a rise in internal pressure. In addition, by containing excess cooling fluid into the expansion tank portion, it is possible to prevent a decrease in cooling efficiency due to a decrease in the amount of cooling fluid.

In, for example, a notebook personal computer having a personal computer body with a keyboard and a display apparatus provided on the personal computer body so as to be freely opened and closed, the above-described liquid-cooled heat dissipating apparatus 1 is installed inside the housing of the personal computer body, and a CPU 19 (a heat generating electronic part) is brought into thermal contact with the heat receiving portion 8 of the lower surface of the hollow circuit substrate 2 of the liquid-cooled heat dissipating apparatus 1. At the time of start-up of the notebook personal computer, cooling fluid is circulated inside the cooling fluid passage 5 by the circulating pump 7. Heat which is generated by the CPU 19 is transmitted to the cooling fluid via the lower metal sheet 4. Then, in the period until the cooling fluid circulates through the cooling fluid circulating passage 5 and returns to the heat receiving portion 8, the heat contained in the cooling fluid is dissipated to the exterior through the upper and lower metal sheets 3 and 4 and particularly in the heat dissipating portion 9, it is dissipated through the lower metal sheet 4 and the heat dissipating fin 18. As a result, the cooling fluid is cooled. By repeating this operation, the heat generated by the CPU 19 is dissipated.

The hollow circuit substrate 2 is manufactured by the method described below.

First, as shown in FIG. 2, by performing press working on an aluminum brazing sheet having a brazing material layer on one surface thereof, the circuit-forming bulging portion 11, the projections 15, and the through holes 16 are simultaneously formed, whereby the upper metal sheet 3 is fabricated. The circuit-forming bulging portion 11 projects toward the side (the upper side) of the aluminum brazing sheet, on which side the brazing material layer is not formed, and thus, the circuit-forming bulging portion 11 opens toward the side (the lower side) of the aluminum brazing sheet, on which side the brazing material layer is formed. Further, by performing press working on an aluminum brazing sheet having a brazing material layer on one surface thereof, the through holes 17 are formed, whereby the lower metal sheet 4 is fabricated. The lower metal sheet 4 serves as a coating-side metal sheet and the upper metal sheet 3 serves as an uncoating-side metal sheet.

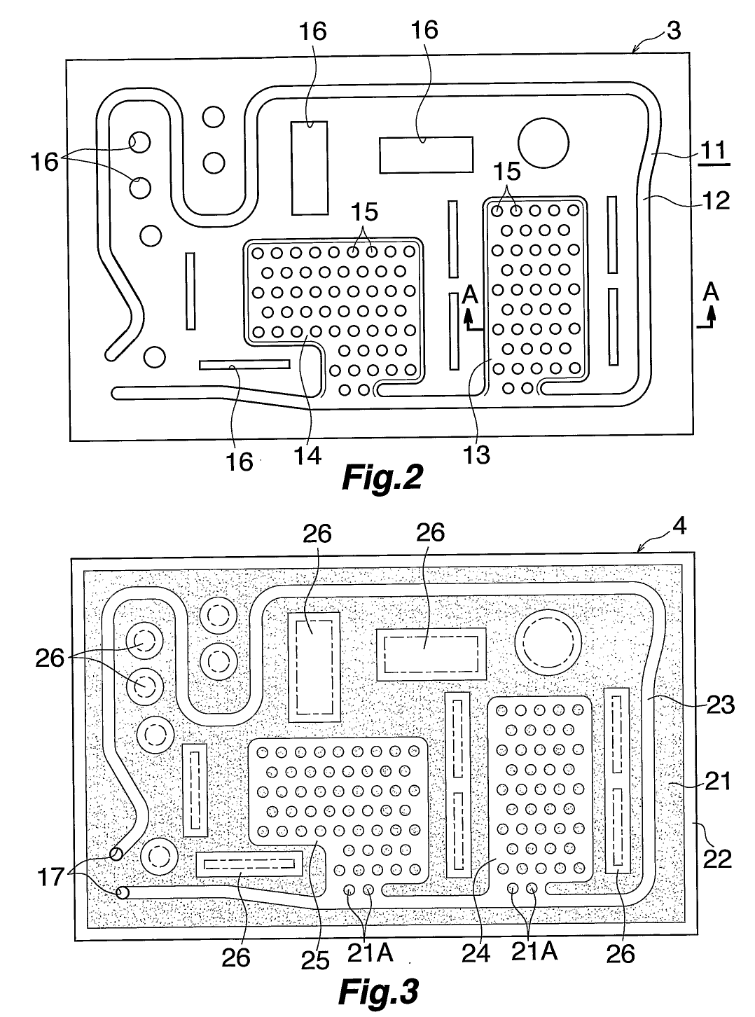

On the other hand, as shown in FIG. 3, a flux film 21 is formed on the top surface (the surface carrying the brazing material layer) of the lower metal sheet 4 by application of a flux suspension by screen printing so as not to overlap the circuit-forming bulging portion 11 and the through holes 16 in the upper metal sheet 3. The flux suspension is prepared through suspension of fluoride-based noncorrosive flux powder in water. The concentration of flux in the flux suspension is preferably 50 to 70% by mass. This is because if the concentration of flux in the flux suspension is less than 50% by mass, repelling or dripping of liquid after coating may occur, while if it exceeds 70% by mass, the viscosity of the flux suspension becomes too high, so uniform coating becomes difficult, and the thickness of the flux film may become nonuniform. The average particle diameter of the flux in the flux suspension is preferably at most 30 μm. If the average particle diameter of the flux exceeds 30 μm, it may become impossible to make the film thickness of the flux film 21 thin and uniform. The mesh size of the screen used in screen printing is determined based on the particle diameter of the flux powder and the necessary amount of flux.

On the top surface of the lower metal sheet 4, first through fifth uncoated portions 22, 23, 24, 25, and 26 which are not coated with the flux suspension are provided in a portion outward of the outer peripheral portion of the flux film 21, in portions corresponding to the first through third portions 12-14 of the circuit-forming bulging portion 11 of the upper metal sheet 3, and in portions corresponding to the through holes 16 of the upper metal sheet 3.

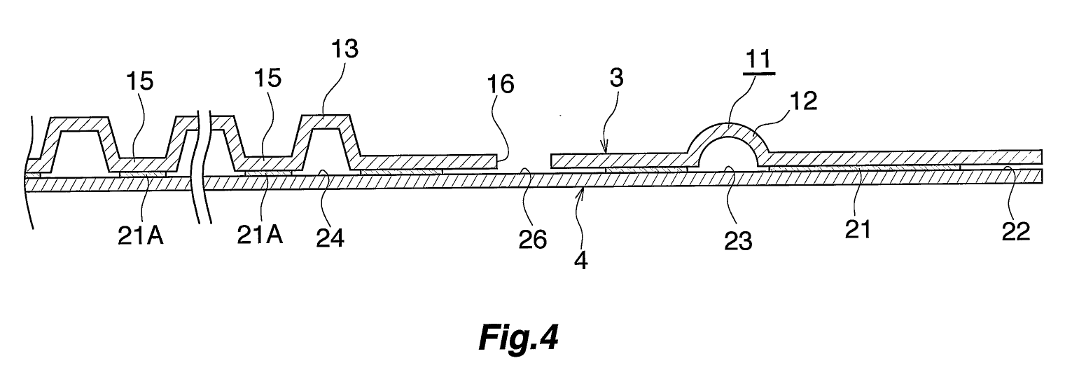

The width of the first uncoated portion 22 is preferably at least 10 mm. In this case, leakage of flux to the exterior during brazing is prevented. The width of the second uncoated portion 23 is preferably at least the width of the first portion 12 of the circuit-forming bulging portion 11 and it is preferably positioned so that when the two metal sheets 3 and 4 are stacked up as described below, both side edges of the second uncoated portion 23 are aligned with both side edges of the first portion 12 or located outwards thereof. In addition, when both metal sheets 3 and 4 are stacked up as described below, the outer peripheral portions of the third and fourth uncoated portions 24 and 25 are preferably aligned with the outer periphery of the second and third portions 13 and 14 of the circuit-forming bulging portion 11 or are located outwards thereof (see FIG. 4). In these cases, flux is prevented from leaking into the first through third portions 12, 13, and 14 of the circuit-forming bulging portion 11 during brazing, and flux is prevented from remaining in the cooling fluid circulating passage 5 after brazing. A flux film 21A is formed by application of a flux suspension in locations corresponding to the end surfaces of the projections 15 of the upper metal sheet 3 in the third and fourth uncoated portions 24 and 25. When both metal sheets 3 and 4 are stacked on each other as described below, the peripheral portions of this flux film 21A are preferably aligned with the peripheral portions of the end surfaces of the projections 15 or are located inwards thereof (see FIG. 4). In this case, flux is prevented from leaking into the circuit-forming bulging portion 11 during brazing. In addition, when both metal sheets 3 and 4 are stacked on each other as described below, the outer peripheral portions of the fifth uncoated portions 26 are preferably positioned outwards of the peripheral portions of the through holes 16 in the upper metal sheet 3, with the distance between the outer peripheral portions of the fifth uncoated portion 26 and the peripheral portions of the through holes 16 in the upper metal sheet 3 preferably being at least 10 mm. In this case, flux is prevented from leaking to the outside during brazing.

Next, both metal sheets 3 and 4 are stacked on each other and temporarily fixed so that their brazing material layers face each other and the opening of the circuit-forming bulging portion 11 in the upper metal sheet 3 is closed off by the lower metal sheet 4 and so that the flux films 21 and 21A are present between the metal sheets 3 and 4 (see FIG. 4). Then, the metal sheets 3 and 4 are brazed to each other using the brazing material layer of the aluminum brazing sheet forming at least one of the metal sheets by heating to a prescribed temperature in a furnace. In this manner, a hollow circuit substrate is manufactured.

Brazing of the heat radiating fin 18 of the liquid-cooled heat dissipating apparatus 1 to the hollow circuit substrate 2 may be carried out simultaneously with the above-described manufacture of the hollow circuit substrate 2.

In the above-described embodiment, a circuit-forming bulging portion 11 is formed only in the upper metal sheet 3, but the invention is not limited thereto, and a circuit-forming bulging portion which bulges downwards may also be formed in the lower metal sheet 4. In this case, a cooling fluid circulating passage in the form of one hollow circuit is formed by the circuit-forming bulging portions 11 in both metal sheets 3 and 4. In addition, in the above-described embodiment, a flux suspension is applied to the upper surface of the lower metal sheet 4, but a flux suspension may be applied to the lower surface of the upper metal sheet 3. Which of the metal sheets the flux suspension is applied to is determined based on shape, ease of operation, and the like. In the above-described embodiment, the hollow circuit substrate 2 is formed from two metal sheets 3 and 4, but the invention is not limited thereto, and it may be formed from three or more metal sheets. In addition, in the above-described embodiment, through holes are formed only in the upper metal sheet 3, but through holes may also be formed in the lower metal sheet 4. In this case, as described above, a flux suspension is applied so as not to overlap the through holes.

In the above-described embodiment, a hollow circuit substrate manufactured by the method of this invention is used in a liquid-cooled heat dissipating apparatus, but a hollow circuit substrate manufactured by the method of this invention can also be used in a planar heat pipe. In this case, the hollow circuit is made endless, its interior is filled with a working fluid, and as a result, a heat pipe portion having a condenser portion and an evaporator portion is formed. Such a planar heat pipe has a heat radiating fin which is installed on at least one surface of the hollow circuit substrate such that the fin is located at a portion corresponding to the condenser portion of the heat pipe portion, and it can be used as a heat dissipating apparatus, for example. The heat dissipating apparatus can be used in a CNC (computer numerical control) machine tool in a state in which a heat generating electronic part thermally contacts a portion corresponding to the evaporator portion of the heat pipe on either surface of the hollow circuit substrate of the planar heat pipe. A heat generating electronic part of a CNC machine tool is, for example, a heat generating electronic part of a controller.

### INDUSTRIAL APPLICABILITY

The method according to the present invention is preferably used for manufacture of a hollow circuit substrate which is used in a liquid-cooled heat dissipating apparatus for dissipating heat which is generated by a heat generating body such as a heat generating electronic component of, for example, a notebook personal computer.

1. A method of manufacturing a hollow circuit substrate, the entire of which is composed of at least two metal sheets which are brazed to each other in a laminated state and in which a bulging hollow circuit is for ed between the metal sheets, the method comprising:
forming a circuit-forming bulging portion in at least one of the two metal sheets for forming a hollow circuit;
printing a flux suspension on a surface of one of the two metal sheets serving as a coating-side metal sheet, the surface facing the other metal sheet serving as an uncoating-side metal sheet, such that the flux suspension does not overlap the circuit-forming bulging portion, whereby a flux film is for ed on the surface of the coating-side metal sheet; and
stacking the metal sheets so as to close off the opening of the circuit-forming bulging portion and brazing the metal sheets.

2. A method of manufacturing a hollow circuit substrate as set forth in claim 1 wherein the printing of the flux suspension is carried out by screen printing.

3. A method of manufacturing a hollow circuit substrate as set forth in claim 1 wherein the concentration of flux in the flux suspension is 50-70% by mass.

4. A method of manufacturing a hollow circuit substrate as set forth in claim 1 wherein the average particle diameter of the flux in the flux suspension is at most 30 μm.

5. A method of manufacturing a hollow circuit substrate as set forth in claim 1 wherein the two metal sheets for forming a hollow circuit are made of aluminum, and of the two metal sheets, at least one of the metal sheets is formed from a aluminum brazing sheet having a brazing material layer on at least one surface, and both metal sheets are brazed to each other using the brazing material layer of the aluminum brazing sheet.

6. A method of manufacturing a hollow circuit substrate as set forth in claim 1 wherein the coating-side metal sheet is coated with the flux suspension except for in its peripheral portion.

7. A method of manufacturing a hollow circuit substrate as set forth in claim 1 wherein a through hole is formed in at least one of the two metal sheets for forming a hollow circuit, and the flux suspension is applied to the coating-side metal sheet so as not to overlap the through hole.

8. A hollow circuit substrate manufactured by the method set forth in claim 1, wherein a bulging hollow circuit is formed between at least one set of two adjoining metal sheets.

9. A liquid-cooled heat dissipating apparatus in which the bulging hollow circuit of the hollow circuit substrate set forth in claim 8 forms a cooling fluid circulating passage, and a heat receiving portion which thermally contacts a heat generating body which is cooled by a cooling fluid flowing within the cooling fluid circulating passage is provided on one surface of the hollow circuit substrate.

10. An electronic apparatus having a housing and a heat generating electronic part disposed within the housing, wherein a liquid-cooled heat-dissipating apparatus as set forth in claim 9 is disposed in the housing, and the heat generating electronic part is thermally contacted by the heat receiving portion of the hollow circuit substrate.

11. A notebook personal computer having a body with a keyboard, and a display apparatus which is provided on the body so as to be freely opened and closed, wherein a liquid-cooled heat dissipating apparatus as set forth in claim 9 is provided in the housing of the body, and a CPU which is disposed within the housing of the body thermally contacts the heat receiving portion.

12. A planar heat pipe in which the bulging hollow circuit of the hollow circuit substrate of claim 8 is endless, in which a working fluid is sealed within the bulging hollow circuit, whereby a heat pipe portion having a condenser portion and an evaporator portion is for ed.

13. A heat dissipating apparatus in which a heat dissipating fin is attached to at least one surface of the planar heat pipe as set forth in claim 12 at a portion corresponding to the condenser portion of the heat pipe portion.

14. A CNC machine tool having a heat dissipating apparatus as set forth in claim 13, wherein a heat generating electronic part thermally contacts the evaporator portion of the heat pipe on at least one surface of the planar heat pipe of the heat dissipating apparatus.
